(19) United States
(12) Patent Application Publication
(10) Pub. No.: US 2011/0070727 A1
(43) Pub. Date: Mar. 24, 2011

(54) Method of Fabricating Semiconductor Device

(75) Inventor: Tomoya Satonaka, Kanagawa (JP)

(73) Assignee: Kabushiki Kaisha Toshiba, Tokyo (JP)

(21) Appl. No.: 12/956,180

(22) Filed: Nov. 30, 2010

Related U.S. Application Data
(62) Division of application No. 12/252,137, filed on Oct. 15, 2008.

(30) Foreign Application Priority Data
Oct. 16, 2007 (JP) 2007-269432

(51) Int. Cl. H01L 21/28

(52) U.S. Cl. 438/595; 257/E21.177

(57) ABSTRACT

A method of fabricating a semiconductor device according to one embodiment includes: forming a gate electrode by shaping a semiconductor film formed above a semiconductor substrate; forming a protective film on a side face of the gate electrode by plasma discharge of a first gas or a second gas, the first gas containing at least one of HBr, Cl₂, CF₄, SF₆, and NF₃ in addition to O₂ and a flow rate of O₂ therein being greater than 80% of the total of the entire flow rate, and the second gas containing at least one of HBr, Cl₂, CF₄, SF₆, and NF₃ in addition to O₂ and N₂ and a flow rate of sum of O₂ and N₂ therein being greater than 80% of the total of the entire flow rate; and removing a residue of the semiconductor film above the semiconductor substrate after forming the protective film.

### CROSS-REFERENCE TO RELATED APPLICATIONS

This application is based upon and claims the benefit of priority from prior Japanese Patent Application No. 2007-269432, filed on Oct. 16, 2007, the entire contents of which are incorporated herein by reference.

### BACKGROUND

It is becoming progressively difficult to form a gate electrode having a desired processed shape by anisotropic dry etching in accordance with miniaturization of semiconductor element in recent years.

A technique to shape a polycrystalline Si film into a gate electrode in a desired shape by etching process during which etching condition such as etching selectivity or the like is changed, has been known. This technique, for example, is disclosed in Japanese Patent Application Laid-Open No. 2006-86295.

According to this technique, after shaping the polycrystalline Si film into the gate electrode through two levels of etching steps, the polycrystalline Si film which remains other than in a region under a hard mask used for etching is completely removed by overetching.

However, since the polycrystalline Si film remaining on a side faces of other members or the like is completely removed, if the overetching is carried out under a condition having a certain level of isotropy, there is a possibility that the etching may reach the side face of the gate electrode (side-etch). As a result, the gate electrode is not in a desired shape any more, furthermore, a width, a position etc. of an offset spacer formed on the side face of the gate electrode becomes non-uniform and it may be difficult to control a position in which an extension region in a source/drain region is formed.

### BRIEF SUMMARY

A method of fabricating a semiconductor device according to one embodiment includes: forming a gate electrode by shaping a semiconductor film formed above a semiconductor substrate; forming a protective film on a side face of the gate electrode by plasma discharge of a first gas or a second gas, the first gas containing at least one of HBr, Cl₂, CF₄, SF₆, and NF₃ in addition to O₂ and a flow rate of O₂ therein being greater than 80% of the total of the entire flow rate, and the second gas containing at least one of HBr, Cl₂, CF₄, SF₆, and NF₃ in addition to O₂ and N₂ and a flow rate of sum of O₂ and N₂ therein being greater than 80% of the total of the entire flow rate; and removing a residue of the semiconductor film above the semiconductor substrate after forming the protective film.

A method of fabricating a semiconductor device according to another embodiment includes: laminating a semiconductor film as a gate material on a semiconductor substrate via an insulating film; forming a predetermined pattern by shaping the semiconductor film; forming a protective film on a side face of the predetermined pattern by plasma discharge of a gas containing O₂ or that containing O₂ and N₂; after forming the protective film, removing an exposed portion of the insulating film and forming a trench in a region in the semiconductor substrate, the region being just under a portion where the insulating film has been removed; and forming an element isolation region by embedding an insulation material into the trench.

A method of fabricating a semiconductor device according to another embodiment includes: laminating a metal film and a semiconductor film on a semiconductor substrate via an insulating film; forming a semiconductor layer of a gate electrode by shaping the semiconductor film; forming a protective film on a side face of the semiconductor layer of the gate electrode by plasma discharge of a gas containing O₂ or that containing O₂ and N₂; and forming a metal layer of the gate electrode by shaping the metal film after forming the protective film.

### BRIEF DESCRIPTION OF THE DRAWINGS

FIGS. 1A to 1M are cross sectional views showing processes for fabricating a semiconductor device according to a first embodiment;

FIGS. 2A to 2L are cross sectional views showing processes for fabricating a semiconductor device according to a second embodiment; and

FIGS. 3A to 3F are cross sectional views showing processes for fabricating a semiconductor device according to a third embodiment.

### DETAILED DESCRIPTION

### First Embodiment

In this embodiment, a gate electrode composed of a semiconductor such as polycrystal Si is formed.

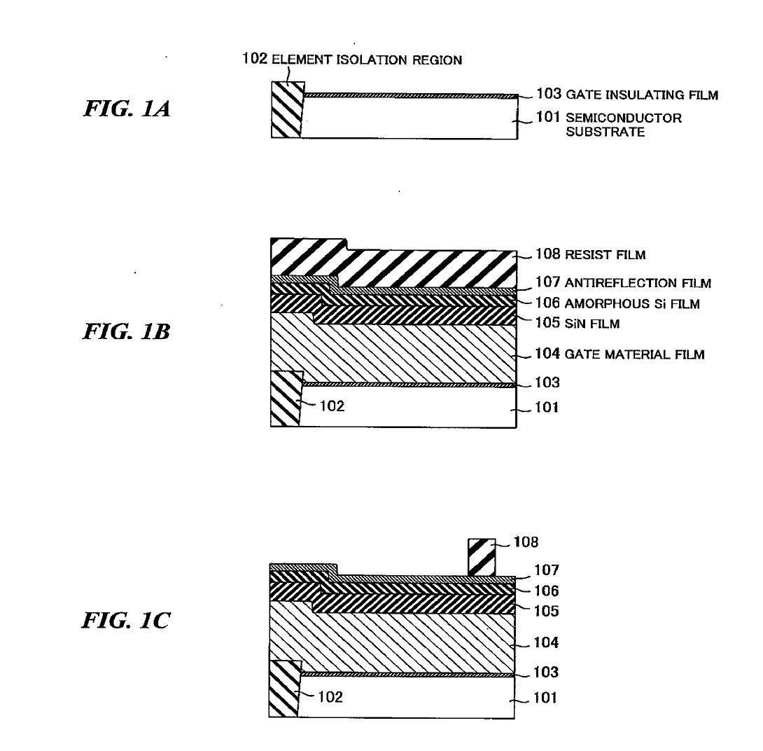

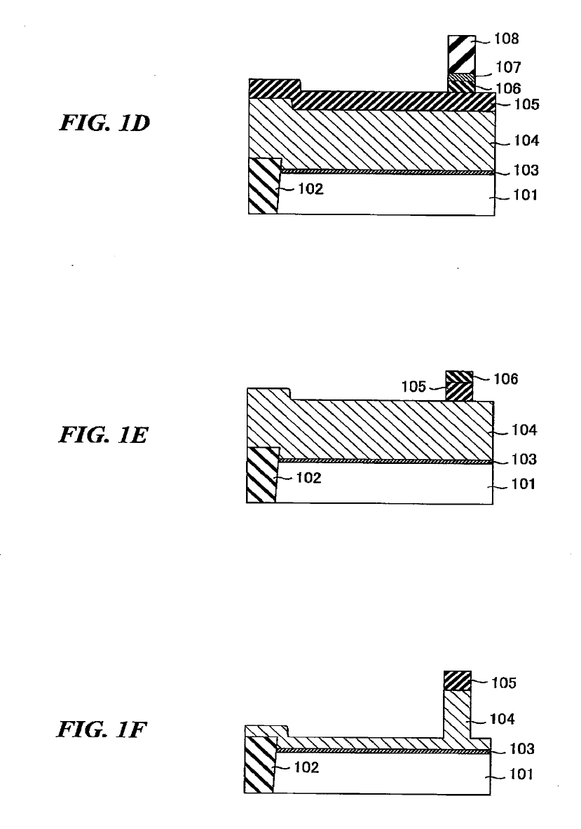

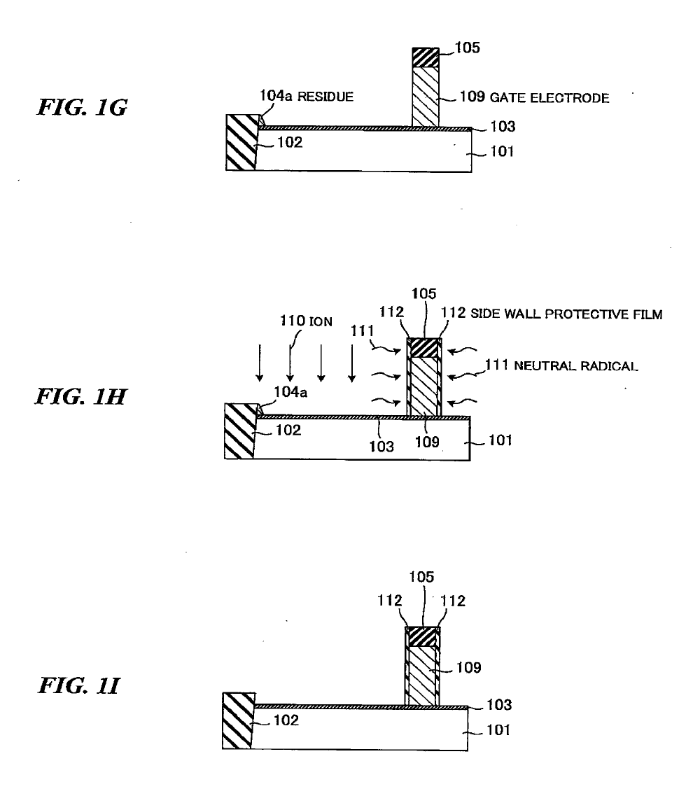

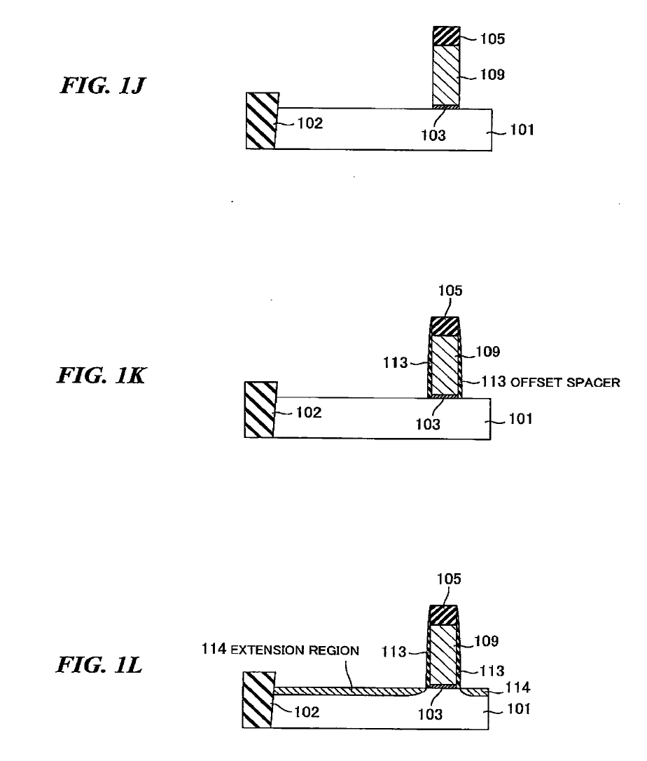

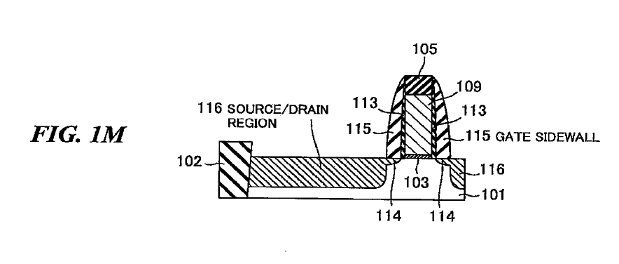

FIGS. 1A to 1M are cross sectional views showing processes for fabricating a semiconductor device according to the first embodiment.

In this embodiment, each member is shaped by RIE (Reactive Ion Etching) using ICP (inductively coupled plasma) etching apparatus, as an example. Furthermore, a film having four layers of a SiN film, an amorphous Si film, an antireflection film and a resist film is used as an etching mask for patterning a gate electrode.

Firstly, as shown in FIG. 1A, an element isolation region 102 having a STI (Shallow Trench Isolation) structure composed of SiO₂ or the like is formed in a semiconductor substrate 101 composed of single crystal Si or the like, and then, a gate insulating film 103 in a thickness of 1.5 nm composed of a silicon dioxide film or the like is formed on the semiconductor substrate 101.

Next, as shown in FIG. 1B, a gate material film 104 in a thickness of 130 nm composed of a polycrystalline Si film or the like, a SiN film 105 in a thickness of 60 nm, an amorphous Si film 106 in a thickness of 40 nm, an antireflection film 107 and a resist film 108, for example, in a thickness of 280 nm, are formed on the gate insulating film 103 and the element isolation region 102.

Next, as shown in FIG. 1C, for example, the resist film 108 is patterned by a projection exposure method using ArF excimer laser beam so as to have a mask size of 90 nm.

Next, as shown in FIG. 1D, the patterns of the patterned resist film 108 is transferred to the antireflection film 107 and the amorphous Si film 106 by etching the antireflection film 107 and the amorphous Si film 106 using the patterned resist film 108 as a mask.

The etching condition for the antireflection film 107 is that pressure is 10 mT, a type of gas and a flow rate are CF₄/O₂=50/50 sccm, source power applied to an upper electrode of an apparatus is 350 W and bias power applied to a lower electrode of the apparatus is 30V.

Furthermore, when etching the amorphous Si film 106, the etching condition is changed during the process. In the first condition, the pressure is 6 mT, the type of gas and the flow rate are HBr/CF₄/Cl₂=150/20/10 sccm, the source power applied to the upper electrode of the apparatus is 600 W and the bias power applied to the lower electrode of the apparatus is 150V. In the second condition, the pressure is 90 mT, the type of gas and the flow rate are HBr/O₂=150/4 sccm, the source power applied to the upper electrode of the apparatus is 800 W and the bias power applied to the lower electrode is 100V. After removing the most part of an etched portion of the amorphous Si film 106 under the first condition, the rest is removed under the second condition.

Next, as shown in FIG. 1E, the resist film 108 and the antireflection film 107 are ashed by ashing treatment and attached materials after the etching are removed using SPM (Sulfuric acid/hydrogen Peroxide Mixture), and then, the pattern of the amorphous Si film 106 is transferred to the SiN film 105 by etching the SiN film 105 using the amorphous Si film 106 as a mask.

The etching condition for the SiN film 105 is that the pressure is 20 mT, the type of gas and the flow rate are CH₃F/O₂/He=80/30/100 sccm, the source power applied to the upper electrode of the apparatus is 400 W and the bias power applied to the lower electrode of the apparatus is 200V.

Next, as shown in FIG. 1F, the gate material film 104 is etched up to a predetermined depth in a middle portion using the patterned SiN film 105 as a mask. Note that, the amorphous Si film 106 is removed during this process.

The etching condition in this process is that the pressure is 6 mT, the type of gas and the flow rate are HBr/CF₄/Cl₂=150/20/10 sccm, the source power applied to the upper electrode of the apparatus is 600 W and the bias power applied to the lower electrode of the apparatus is 150V. It is a condition with strong anisotropy for accurately transferring the pattern of the SiN film 105 to the gate material film 104. Note that, since the gate insulating film 103 is not exposed in this stage, the etching selectivity of the gate material film 104 and the gate insulating film 103 is not necessarily large. Furthermore, the predetermined depth to stop etching under this condition may be judged by a preset etching time or by monitoring the thickness of the etched portion of the gate material film 104.

Next, as shown in FIG. 1G, the gate material film 104 is shaped into a gate electrode 109 by continuing to etch the gate material film 104 under the changed condition.

The etching condition in this process is that the pressure is 15 mT, the type of gas and the flow rate are HBr/O₂=150/4 sccm, the source power applied to the upper electrode of the apparatus is 500 W and the bias power applied to the lower electrode of the apparatus is 45V. Since the gate insulating film 103 is started to be exposed during this etching process, the etching selectivity of the gate material film 104 and the gate insulating film 103 is large in this condition.

However, as shown in FIG. 1G, the gate material film 104 is not completely removed and remains as a residue 104a in the vicinity of the side face of the element isolation region 102. This is the remains of a portion having a thickness larger than that of peripheral areas which could not be completely removed due to steps between upper surfaces of the element isolation region 102 and the gate insulating film 103.

Note that, here, when continuing the etching until the residue 104a is completely removed, the etching reaches the side face of the gate electrode 109 and it may become a side-etched shape which affects adversely to a post-process.

Next, as shown in FIG. 1H, discharge is carried out under the condition that the pressure is 80 mT, the type of gas and the flow rate are N₂/O₂/HBr=100/100/10 sccm, the source power applied to the upper electrode of the apparatus is 120 W, the bias power applied to the lower electrode of the apparatus is 150V and the discharge duration is 10 sec.

At this time, the introduced gas is ionized and neutrally radicalized by plasma excitation. A neutral radical 111 such as O-radical, N-radical or the like is not affected by the applied voltage, attaches to an object moving isotropically, and reacts chemically. Then, a side wall protective film 112 composed of a SiON film or the like is formed on the surface of the gate electrode 109 by oxidative reaction and nitriding reaction with the gate electrode 109. Note that, an SiO₂ film, an SiN film or the like may be contained in the side wall protective film 112 besides the SiON film.

Meanwhile, an ion 110 such as an HBr-ion, an O-ion an N-ion or the like is accelerated by the applied voltage and is anisotropically implanted into the surface of the semiconductor substrate 101 in a substantially vertical direction.

Here, the neutral radical 111 also reacts with the residue 104a and start to forma film similar to the side wall protective film 112 on the surface thereof, however, this film continues to be trimmed by the ion 110 implanted in a direction substantially vertical to the surface of the semiconductor substrate 101 without having time to be formed. Therefore, the film similar to the side wall protective film 112 is not formed on the surface of the residue 104a, eventually. Note that, since the direction that the ion is implanted is substantially vertical to the surface of the semiconductor substrate 101, the side wall protective film 112 on the side face of the gate electrode 109 is barely trimmed.

Next, as shown in FIG. 1I, the residue 104a is removed by the RIE under the condition that the pressure is 90 mT, the type of gas and the flow rate are HBr/O₂=150/4 sccm, the source power applied to the upper electrode of the apparatus is 800 W and the bias power applied to the lower electrode of the apparatus is 100V.

At this time, although the etching is carried out under the isotropic condition for effectively removing the residue 104a, since the side wall protective film 112 is formed on the side face of the gate electrode 109, it is possible to prevent the gate electrode 109 from being side-etched.

Note that, in the process for forming the side wall protective film 112 shown in FIG. 1H, it is possible to oxidize and nitride, or, oxidize the gate electrode 109 using a gas containing at least one of HBr, Cl₂, CF₄, SF₆, and NF₃ in addition to O₂ and N₂, or a gas containing at least one of HBr, Cl₂, CF₄, SF₆, and NF₃ in addition to O₂, or the like, besides the above-mentioned mixed gas of N₂, O₂ and HBr. Here, any of HBr, Cl₂, CF₄, SF₆, and NF₃ functions as the ion 110 shown in FIG. 1H by ionizing.

When using the gas containing at least one of HBr, Cl₂, CF₄, SF₆, and NF₃ in addition to O₂ and N₂, the flow rate of sum of O₂ and N₂ is set to be greater than 80% of the total flow rate of the entire gas, furthermore, preferably smaller than 96%. This is because it is difficult to form the side wall protective film 112 having sufficient thickness when the flow rate of sum of the O₂ and N₂ is 80% or less of the total flow rate of HBr (Cl₂, CF₄, SF₆, NF₃), O₂ and N₂, which may result in that the gate electrode 109 is side-etched. Furthermore, when being 96% or more, a film similar to the side wall protective film 112 is formed also on the surface of the residue 104a and it may become difficult to remove the residue 104a without damaging the gate insulating film 103 and the semiconductor substrate 101 just under thereof in the process shown in FIG. 1I.

When using the gas containing at least one of HBr, Cl₂, CF₄, SF₆, and NF₃ in addition to O₂, the flow rate of O₂ is set to be greater than 80% of the total flow rate of the entire gas, furthermore, preferably smaller than 96% according to the same reason. Note that, even when using the gas containing at least one of HBr, Cl₂, CF₄, SF₆, and NF₃ in addition to O₂ and N₂, the flow rate of the O₂ is preferably greater than 10% of the total flow rate of the entire gas.

Furthermore, the formation of the side wall protective film 112 shown in FIG. 1H and the removal of the residue 104a shown in FIG. 1I can be continuously carried out in the same chamber only by changing an operating condition of the etching apparatus.

Next, as shown in FIG. 1J, the side wall protective film 112 is removed by wet etching using diluted hydrofluoric acid, and then, the gate insulating film 103 is etched using the SiN film 105 and the gate electrode 109 as a mask.

Next, as shown in FIG. 1K, an offset spacer 113 is formed on the side faces of the SiN film 105, the gate electrode 109 and the gate insulating film 103. At this process, since the gate electrode 109 is not side-etched, it is possible to accurately form the offset spacer 113 with a desired width.

Next, as shown in FIG. 1L, a conductivity type impurity is implanted into the semiconductor substrate 101 by an ion implantation procedure or the like using the offset spacer 113 and the SiN film 105 as a mask, which results in that an extension region 114 of a source/drain region is formed.

Since a position where the extension region 114 is formed is determined by the width and the position of the offset spacer 113, it is required to control them accurately. Note that, even when the extension region 114 is formed by forming a trench on the surface of the semiconductor substrate 101 and embedding an epitaxial crystal thereto, since the trench is formed by etching using the offset spacer 113 and the SiN film 105 as a mask, the position where the extension region 114 is formed is determined by the width and the position of the offset spacer 113, in the same way.

Next, as shown in FIG. 1M, after forming a gate sidewall 115 composed of an insulating material on the side face of the offset spacer 113, a source/drain region 116 is formed by, for example, implanting a conductivity type impurity into the semiconductor substrate 101 by an ion implantation procedure or the like using the gate sidewall 115 and the SiN film 105 as a mask.

Then, after removing the SiN film 105, an interlayer insulating film, a contact, a wiring or the like are formed on the semiconductor substrate 101 by a normal fabrication process even though it is not illustrated.

According to this first embodiment, it is possible to remove the residue 104a in vicinity of the side face of the element isolation region 102 or the like without side-etching the gate electrode 109. Since the gate electrode 109 is not side-etched, it is possible to accurately form the offset spacer 113 with a desired width in a desired position, and to prevent variation of performance of the transistor. Furthermore, since it is possible to remove the residue 104a on the side face of the element isolation region 102, it is possible to inhibit a generation of short circuit via the residue 104a between multiple transistors in the same element region surrounded by the same element isolation region 102.

Note that, in this embodiment, the flow to remove the residue 104a in vicinity of the side face of the element isolation region 102 is explained as an example, however, it is possible to remove a residue of the gate material film 104 in other positions.

### Second Embodiment

In this embodiment, a stack gate structure composing a flash memory is formed.

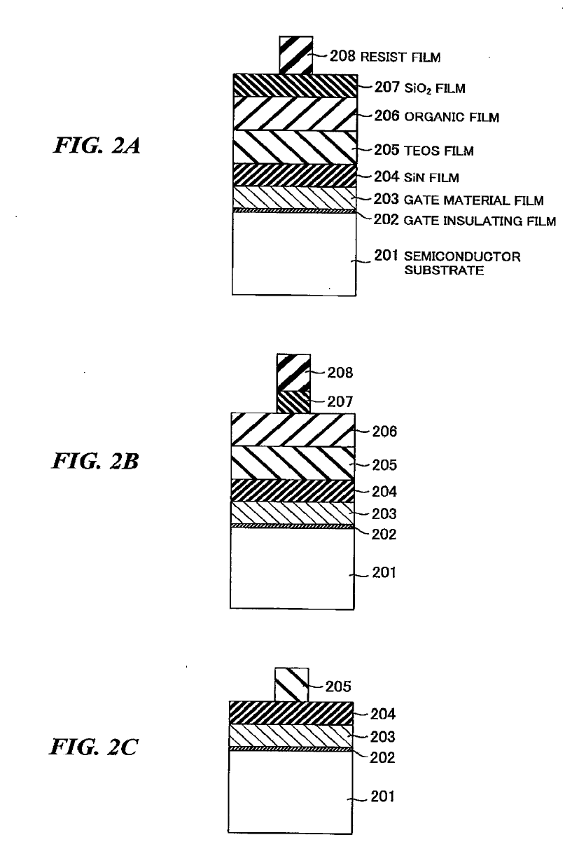

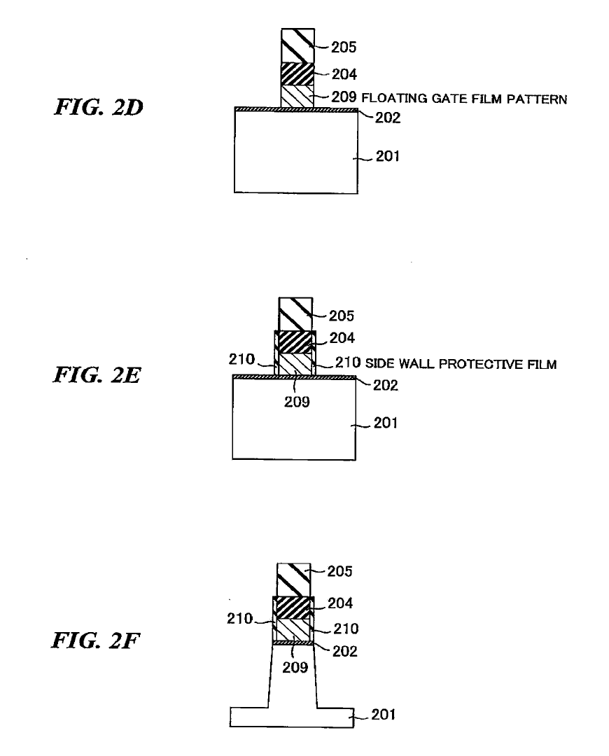

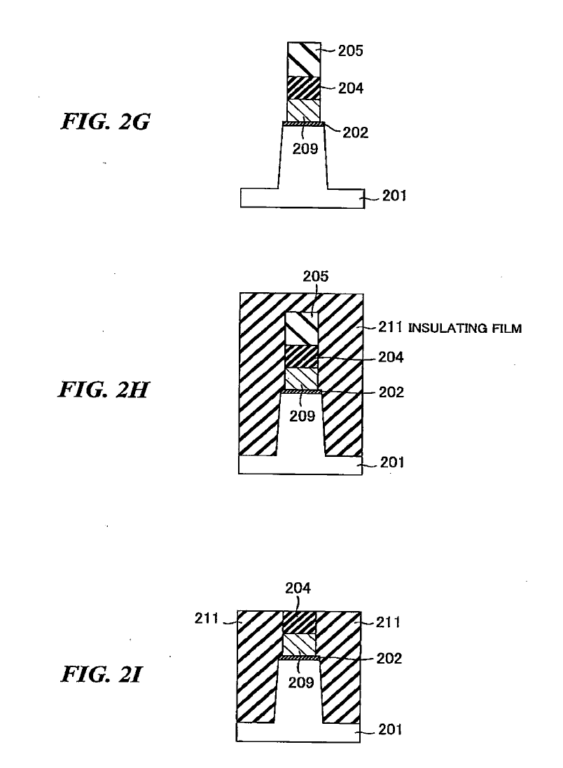

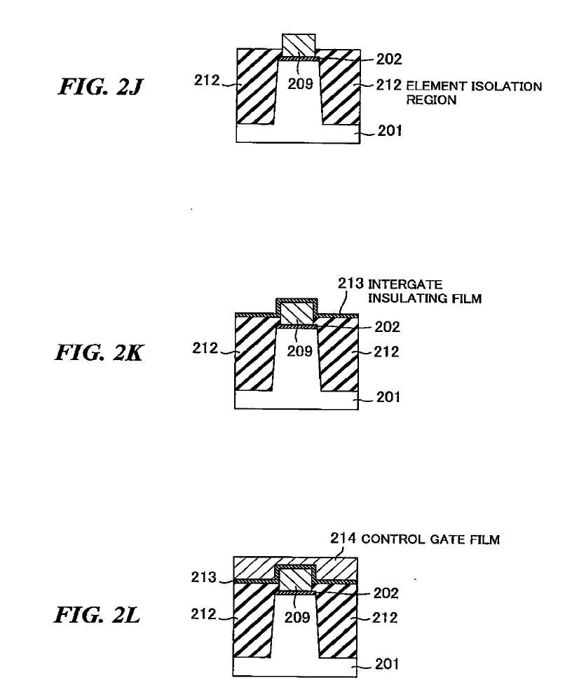

FIGS. 2A to 2L are cross sectional views showing processes for fabricating a semiconductor device according to the second embodiment.

In this embodiment, each member is shaped by RIE using ICP etching apparatus, as an example. Furthermore, a film having five layers of a SiN film, a TEOS (Tetraethoxysilane) film, an organic film, an SiO₂ film and a resist film is used as an etching mask for forming a predetermined pattern on the gate material film which becomes a floating gate.

Firstly, as shown in FIG. 2A, a gate insulating film 202 in a thickness of 6 nm composed of a silicon dioxide film or the like, a gate material film 203 in a thickness of 80 nm composed of a amorphous Si film containing P or the like, a SiN film 204 in a thickness of 100 nm, a TEOS film 205 in a thickness of 300 nm, an organic film 206 in a thickness of 300 nm and a SiO₂ film 207 in a thickness of 80 nm are formed on a semiconductor substrate 201 composed of a single crystal Si or the like. Here, the gate material film 203 and the SiN film 204 are formed by a CVD (Chemical Vapor Deposition) method, and the organic film 206 and the SiO₂ film 207 are formed by a spin coating method. Furthermore, a resist film 208 is pattern formed on the SiO₂ film 207 using a photolithographic technique.

Next, as shown in FIG. 2B, the pattern of the patterned resist film 208 is transferred to the SiO₂ film 207 by etching the SiO₂ film 207 using the patterned resist film 208 as a mask. Here, the SiO₂ film 207 is etched using a gas such as CHF₃ or the like.

Next, as shown in FIG. 2C, the TEOS film 205 is patterned. Concretely, processes described below are carried out. Firstly, the pattern of the resist film 208 and the SiO₂ film 207 is transferred to the organic film 206 by etching the organic film 206 using the resist film 208 and the SiO₂ film 207, which have been patterned in the process shown in FIG. 2B, as a mask. Note that, the resist film 208 is removed during this process. Following this, the pattern of the organic film 206 and the SiO₂ film 207 is transferred to the TEOS film 205 by etching the TEOS film 205 using the patterned organic film 206 and the SiO₂ film 207 as a mask. Furthermore, after patterning the TEOS film 205, the organic film 206 is ashed by ashing treatment and attached materials after the etching are removed by SPM. Note that, the SiO₂ film 207 is removed during this process. Here, the organic film 206 is etched using a gas containing O₂ and the TEOS film 205 is etched using a CF-based gas.

Next, as shown in FIG. 2D, the SiN film 204 and the gate material film 203 are etched using the patterned TEOS film 205 as a mask, and the gate material film 203 is isolated along a word line direction between cells of the flash memory and shaped into a floating gate film pattern 209.

The etching condition of the SiN film 204 is that the pressure is 15 mT, the type of gas and the flow rate are CHF₃/O₂=100/50 sccm, the source power applied to the upper electrode of the apparatus is 400 W and the bias power applied to the lower electrode of the apparatus is 400V. Furthermore, the etching condition of the gate material film 203 is that the pressure is 10 mT, the type of gas and the flow rate are HBr/O₂/CF₄=245/5/50 sccm, the source power applied to the upper electrode of the apparatus is 600 W and the bias power applied to the lower electrode of the apparatus is 100V.

Note that, if continuing to etch the gate insulating film 202 and the semiconductor substrate 201, there is a possibility that the floating gate film pattern 209 may be side-etched.

Next, as shown in FIG. 2E, discharge is carried out under the condition that the pressure is 80 mT, the type of gas and the flow rate are O₂=100 sccm, the source power applied to the upper electrode of the apparatus is 1200 W, the bias power applied to the lower electrode of the apparatus is 0V and the discharge duration is 30 sec, and a side wall protective film 210 is formed so as to cover side faces of the floating gate film pattern 209 by oxidizing the side face of the floating gate film pattern 209. For example, when the floating gate film pattern 209 is composed of polycrystal Si which is formed by crystallizing amorphous Si by heat treatment, the main component of the side wall protective film 210 is SiO₂.

Next, as shown in FIG. 2F, the gate insulating film 202 is shaped by etching under the condition that the pressure is 5 mT, the type of gas and the flow rate are CF₄=100 sccm, the source power applied to the upper electrode of the apparatus is 1000 W and the bias power applied to the lower electrode of the apparatus is 200V. Following this, the semiconductor substrate 201 is dug down to a predetermined depth by etching under the condition that the pressure is 20 mT, the type of gas and the flow rate are HBr/Cl₂/CF₄/O₂=250/20/50/5 sccm, the source power applied to the upper electrode of the apparatus is 1000 W and the bias power applied to the lower electrode of the apparatus is 200V.

At this time, since the side wall protective film 210 is formed on the side face of the floating gate film pattern 209, it is possible to prevent the floating gate film pattern 209 from being side-etched.

Next, as shown in FIG. 2G, wet etching using diluted hydrofluoric acid is applied to the surface of the etched semiconductor substrate 201 as a post-process, and the side wall protective film 210 is removed at the same time.

Next, as shown in FIG. 2H, an insulating film 211 composed of SiO₂ or the like is deposited allover the semiconductor substrate 201.

Next, as shown in FIG. 2I, the CMP (Chemical Mechanical Polishing) is carried out using an upper surface of the SiN film 204 as a stopper so as to flatten the insulating film 211 and to remove the TEOS film 205.

Next, as shown in FIG. 2J, the insulating film 211 is shaped into an element isolation region 212 by etching-back by the RIE and the SiN film 204 is removed. At this time, it is preferable that the upper surface of the element isolation region 212 is positioned at the height between upper and lower surfaces of the floating gate film pattern 209.

Next, as shown in FIG. 2K, an intergate insulating film 213 composed of SiO₂ or the like is formed on the floating gate film pattern 209 and the element isolation region 212.

Next, as shown in FIG. 2L, a control gate film 214 composed of polycrystal Si or the like is formed on the intergate insulating film 213.

After that, a stack gate structure is formed by shaping the control gate film 214, the intergate insulating film 213 and the floating gate film pattern 209 in a word line shape by, for example, a lithography method and the RIE, and a source/drain is formed by implanting an impurity ion between the stack gate structures of the semiconductor substrate 201, which may result in that a memory cell is obtained, even though it is not illustrated.

According to this second embodiment, it is possible to etch the semiconductor substrate 201 for forming the element isolation region 212 without side-etching the floating gate film pattern 209 in processes for fabricating a semiconductor device having a stack gate structure. As a result, it is possible to prevent a degradation of reliability of the semiconductor device by obtaining a floating gate in a desired shape.

Note that, in this embodiment, although it is explained that the side wall protective film 210 is formed by oxidizing the side face of the floating gate film pattern 209 by plasma discharge of the gas containing O₂ as an example, a side wall protective film may be formed by oxidizing and nitriding the side face of the floating gate film pattern 209 by plasma discharge of the gas containing O₂ and N₂, and at this time, the flow rate of O₂ is preferably greater than 10% of the total flow rate of the entire gas.

### Third Embodiment

In this embodiment, a gate electrode having a two-layer structure of a semiconductor layer and a metal layer is formed.

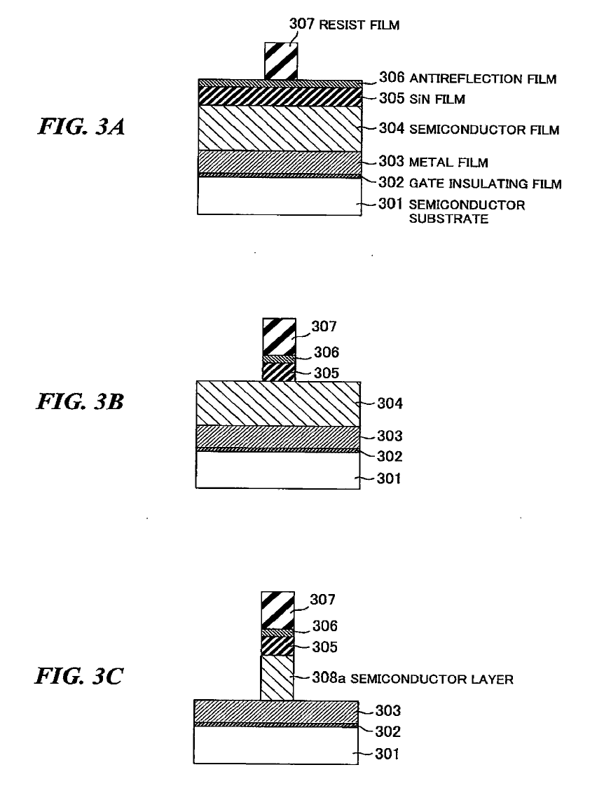

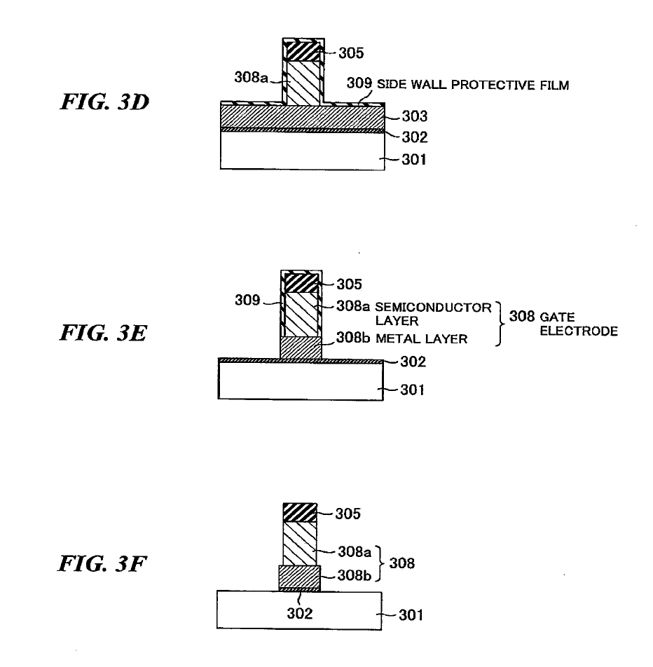

FIGS. 3A to 3F are cross sectional views showing processes for fabricating a semiconductor device according to the third embodiment.

In this embodiment, each member is shaped by the RIE using ICP etching apparatus, as an example. Furthermore, a film having three layers of a SiN film, an antireflection film and a resist film is used as an etching mask for patterning a gate electrode.

Firstly, as shown in FIG. 3A, a gate insulating film 302 in a thickness of 3 nm composed of a HfO film or the like, a metal film 303 in a thickness of 30 nm composed of a TiN film or the like, a semiconductor film 304 in a thickness of 70 nm composed of polycrystal Si or the like, a SiN film 305 in a thickness of 50 nm and an antireflection film 306 in a thickness of 80 nm are formed on a semiconductor substrate 301 composed of a single crystal Si or the like. Here, the metal film 303 is formed by a PVD (Physical Vapor Deposition) method and the semiconductor film 304 is formed by the CVD method. Furthermore, a resist film 307 is pattern formed on the antireflection film 306 by the photolithographic technique using the projection exposure method using ArF excimer laser beam.

Next, as shown in FIG. 3B, the patterns of the patterned resist film 307 is transferred to the antireflection film 306 and the SiN film 305 by etching the antireflection film 306 and the SiN film 305 using the patterned resist film 307 as a mask.

The etching condition for the antireflection film 306 is that the pressure is 10 mT, the type of gas and the flow rate are CF₄/O₂=50/50 sccm, the source power applied to the upper electrode of the apparatus is 350 W and the bias power applied to the lower electrode of the apparatus is 30V.

Furthermore, the etching condition of the SiN film 305 is that the pressure is 20 mT, the type of gas and the flow rate are CH₃F/O₂/He=80/30/100 sccm, the source power applied to the upper electrode of the apparatus is 400 W and the bias power applied to the lower electrode of the apparatus is 400V.

Next, as shown in FIG. 3C, the semiconductor film 304 is shaped into a semiconductor layer 308a by etching using the resist film 307, the antireflection film 306 and the SiN film 305, which have been patterned, as a mask. After that, furthermore, a residue of the semiconductor film 304 remaining on the metal film 303 or the like is removed by overetching.

The etching condition for shaping the semiconductor film 304 is that the pressure is 6 mT, the type of gas and the flow rate are HBr/O₂=300/5 sccm, the source power applied to the upper electrode of the apparatus is 600 W and the bias power applied to the lower electrode of the apparatus is 200V, and the etching condition for removing the residue of the semiconductor film 304 is that the pressure is 90 mT, the type of gas and the flow rate are HBr/O₂=150/4 sccm, the source power applied to the upper electrode of the apparatus is 800 W and the bias power applied to the lower electrode of the apparatus is 300V. Note that, the overetching for removing the residue of the semiconductor film 304 is conducted in a setting that the semiconductor film 304 is etched 40 nm.

Next, as shown in FIG. 3D, discharge is carried out under the condition that the pressure is 80 mT, the type of gas and the flow rate are O₂=100 sccm, the source power applied to the upper electrode of the apparatus is 1200 W, the bias power applied to the lower electrode of the apparatus is 150V and the discharge duration is 30 sec, and a side wall protective film 309 is formed by oxidizing the side face of the semiconductor layer 308a. For example, when the semiconductor layer 308a is composed of polycrystal Si, the main component of the side wall protective film 309 is SiO₂. Here, the side wall protective film 309 may be formed on the side face and the upper surface of the SiN film 305 and the upper surface of the metal film 303. Note that, the resist film 307 and the antireflection film 306 are removed during this process.

Next, as shown in FIG. 3E, after removing the side wall protective film 309 and a natural oxide film on the upper surface of the metal film 303, the metal film 303 is shaped into a metal layer 308b by etching. Furthermore, the residue of the metal film 303 remaining on the upper surface of the gate insulating film 302 or the like is removed by overetching. Here, the metal layer 308b composes a gate electrode 308 with the semiconductor layer 308a which is an upper layer.

The etching condition for removing the side wall protective film 309 and the natural oxide film on the upper surface of the metal film 303 is that the pressure is 4 mT, the type of gas and the flow rate are Cl₂=100 sccm, the source power applied to the upper electrode of the apparatus is 500 W, the bias power applied to the lower electrode of the apparatus is 100V and the discharge duration is 6 sec, the etching condition for shaping the metal film 303 is that the pressure is 6 mT, the type of gas and the flow rate are HBr/Cl₂/O₂=120/50/1.2 sccm, the source power applied to the upper electrode of the apparatus is 575 W and the bias power applied to the lower electrode of the apparatus is 70V, and the etching condition for removing the residue of the metal film 303 is that the pressure is 55 mT, the type of gas and the flow rate are HBr/Cl₂/O₂=120/35/1.2 sccm, the source power applied to the upper electrode of the apparatus is 575 W, the bias power applied to the lower electrode of the apparatus is 70V and the discharge duration is 30 sec.

In this process, since the side face of the semiconductor layer 308a is covered by the side wall protective film 309, the etching does not reach the semiconductor layer 308a. When the side wall protective film 309 is not formed on the side face of the semiconductor layer 308a, since the gas containing a lot of Cl is used for shaping the metal film 303 and removing the residue of the metal film 303 as mentioned above, there is a possibility that the semiconductor layer 308a may be side-etched.

Next, as shown in FIG. 3F, the side wall protective film 309 is removed by wet etching using diluted hydrofluoric acid, and then, the gate insulating film 302 is etched using the gate electrode 308 or the like as a mask.

After that, similarly to the first embodiment, an offset spacer, a gate sidewall and a source/drain region including an extension region or the like are formed even though it is not illustrated.

According to this third embodiment, it is possible to etch the metal film 303 for forming the metal layer 308b without side-etching the semiconductor layer 308a in processes for fabricating the gate electrode 308 having a two-layer structure comprising the semiconductor layer 308a and the metal layer 308b. As a result, it is possible to prevent a degradation of reliability of the semiconductor device by obtaining the gate electrode 308 in a desired shape.

Note that, in this embodiment, although it is explained that the side wall protective film 309 is formed by oxidizing the side face of the semiconductor layer 308a by plasma discharge of the gas containing O₂ as an example, a side wall protective film may be formed by oxidizing and nitriding the side face of the semiconductor layer 308a by plasma discharge of the gas containing O₂ and N₂, and at this time, the flow rate of O₂ is preferably greater than 10% of the total flow rate of the entire gas.

### Other Embodiments

It should be noted that an embodiment is not intended to be limited to the above-mentioned first to third embodiments, and the various kinds of changes thereof can be implemented by those skilled in the art without departing from the gist of the invention. For example, although the ICP etching apparatus is used as the RIE apparatus in the above-mentioned each embodiment, it is not limited thereto in reality, for example, a parallel plate type of etching apparatus may be used.

In addition, the constituent elements of the above-mentioned embodiments can be arbitrarily combined with each other without departing from the gist of the invention.

1. A method of fabricating a semiconductor device, comprising;
forming a gate electrode by shaping a semiconductor film formed above a semiconductor substrate;
forming a protective film on a side face of the gate electrode by plasma discharge of a first gas or a second gas, the first gas containing at least one of HBr, Cl₂, CF₄, SF₆, and NF₃ in addition to O₂ and a flow rate of O₂ therein being greater than 80% of the total of the entire flow rate, and the second gas containing at least one of HBr, Cl₂, CF₄, SF₆, and NF₃ in addition to O₂ and N₂ and a flow rate of sum of O₂ and N₂ therein being greater than 80% of the total of the entire flow rate; and
removing a residue of the semiconductor film above the semiconductor substrate after forming the protective film.

2. The method of fabricating a semiconductor device according to claim 1, wherein formation of the protective film and removal of the residue of the semiconductor film are carried out in the same chamber.

3. The method of fabricating a semiconductor device according to claim 1, wherein the residue of the semiconductor film in the vicinity of a side face in an element isolation region formed on the semiconductor substrate is removed.

4. The method of fabricating a semiconductor device according to claim 1, wherein the protective film is formed by oxidizing, or, oxidizing and nitriding the side face of the gate electrode by the plasma discharge of the first gas or the second gas.

5. The method of fabricating a semiconductor device according to claim 4, wherein the protective film comprises SiON.

6. The method of fabricating a semiconductor device according to claim 1, wherein the residue of the semiconductor film on the semiconductor substrate is removed by isotropic etching.

7. The method of fabricating a semiconductor device according to claim 1, wherein the protective film protects the gate electrode to prevent the side face of the gate electrode from being side-etched when removing the residue of the semiconductor film above the semiconductor substrate.

8. The method of fabricating a semiconductor device according to claim 1, wherein the flow rate of O₂ is smaller than 96% of the total of the entire flow rate in the first gas.

9. The method of fabricating a semiconductor device according to claim 1, wherein the flow rate of sum of O₂ and N₂ is smaller than 96% of the total of the entire flow rate in the second gas.

10. The method of fabricating a semiconductor device according to claim 1, wherein the flow rate of O₂ is greater than 10% of the total of the entire flow rate in the second gas.

11. The method of fabricating a semiconductor device according to claim 1, wherein an offset spacer is formed on the side face of the gate electrode after removing the residue of the semiconductor film above the semiconductor substrate.

12-20. (canceled)
